(19) United States
(12) Patent Application Publication
(10) Pub. No.: US 2015/0224886 A1
(43) Pub. Date: Aug. 13, 2015

(54) INVERTER

(71) Applicant: Takahiro Kakizaki, Fujisawa-shi (JP)

(72) Inventor: Takahiro Kakizaki, Fujisawa-shi (JP)

(73) Assignee: Komatsu Ltd.,, Minato-ku, Tokyo (JP)

(21) Appl. No.: 14/429,775

(22) PCT Filed: Oct. 18, 2012
(86) PCT No.: PCT/JP2012/076972

§ 371 Date: Mar. 19, 2015

(30) Foreign Application Priority Data
Sep. 20, 2012 (JP) 2012-207139

(51) Int. Cl. B60L 11/18; H05K 5/03; H05K 5/02; E02F 9/08; H05K 5/00

(52) U.S. Cl. CPC B60L 11/1812; E02F 9/0858; H05K 5/0004; H05K 5/0247; H05K 5/03

(57) ABSTRACT

An inverter includes: a step-up transformer; an upper cover for covering the step-up transformer; a terminal attached to the upper cover and electrically connected to the step-up transformer; a terminal case attached to the upper cover to cover the terminal and attachable with a connector to be plugged into and unplugged from the terminal; a first positioning unit provided to the upper cover and the terminal to position the upper cover and the terminal relative to each other; and a second positioning unit provided to the upper cover and the terminal case to position the upper cover and the terminal case relative to each other.

### TECHNICAL FIELD

The present invention relates to an inverter. In particular, the present invention relates to, for instance, an inverter installed in a hybrid work machine.

### BACKGROUND ART

A hybrid hydraulic excavator, which is typically known as a hybrid work machine, includes a crawler undercarriage, working equipment including a boom, an arm and a bucket, and a rotary upper structure provided on the crawler undercarriage, the crawler undercarriage and the working equipment being hydraulically driven, the rotary upper structure being driven with electric energy. In the hybrid hydraulic excavator, an electric power is not only generated by a power-generating motor driven by an engine, but also regenerated by a rotary electric motor during braking a rotary motion. The obtained electric power is stored in a capacitor through an inverter and supplied to the rotary electric motor, which is configured to drive the rotary upper structure to rotate, through the inverter.

As disclosed in Patent Literature 1, the inverter may include: a cooler with a cooling water circuit; upper and lower covers for covering the cooler; a step-up transformer; a driving element for driving a power-generating motor; and a driving element for driving a rotary electric motor, the step-up transformer and the driving elements for driving the power-generating motor and the rotary electric motor being housed in an inner space defined by the upper and lower covers. A plurality of terminals electrically connected to the step-up transformer and the driving elements are disposed on the upper cover of the inverter.

The terminals are covered by a terminal case attached to the upper cover. The terminal case includes a connector attachment portion, to which a connector of a power cable is attached such that a connector plug is plugged into a terminal socket and electrically connected thereto. Such an electrical connection enables the electric power to be stored in and supplied from the capacitor through the inverter.

### CITATION LIST

### Patent Literature(s)

Patent Literature 1: JP-A-2012-112102

### SUMMARY OF THE INVENTION

### Problem(s) to be Solved by the Invention

The above typical inverter, however, requires relative positioning between the upper cover, the terminal case, and the terminals housed in the terminal case. Such positioning requires a specific positioning jig and is thus complicated due to, for instance, a time-consuming installation of the positioning jig.

It should be noted that when the positioning is properly performed with the positioning jig, an excellent inner-surface seal is provided between the connector of the power cable and the terminal case. Further, the connector plug can be smoothly plugged into the terminal socket, which results in preventing generation of stress on an electrically connected part. In a work machine, especially a construction machine, it is important to ensure sealability and generate no stress. For instance, dew condensation water or the like entering the inverter through the sealed part is supposed to considerably reduce the lifetime of the driving element of the inverter and the like. Further, since the inverter is always subjected to vibration during an operation, the connected part should be damaged as a result of a continuous operation under stress and thus the electrically connected state cannot be maintained.

An object of the invention is to provide an inverter including an inverter cover such as an upper cover, terminals, and a terminal case, which are capable of being easily positioned relative to one another.

### Means for Solving the Problem(s)

According to a first aspect of the invention, an inverter includes: an electronic component; an inverter cover for covering the electronic component; a terminal attached to the inverter cover and electrically connected to the electronic component; a terminal case attached to the inverter cover to cover the terminal, the terminal case being attachable with a connector to be plugged into and unplugged from the terminal; a first positioning unit provided to the inverter cover and the terminal to position the inverter cover and the terminal relative to each other; and a second positioning unit provided to the inverter cover and the terminal case to position the inverter cover and the terminal case relative to each other.

According to a second aspect of the invention, the terminal case is provided with a connector-insertion opening through which the connector is inserted, the connector has an outer circumferential surface provided with a seal member, and the connector-insertion opening has an inner circumferential surface defining a seal surface to be brought into close contact with the seal member.

According to a third aspect of the invention, the terminal includes a terminal bracket including: a terminal-side attachment surface to be brought into contact with the inverter cover; and a socket-side attachment portion attached with a socket into which a plug of the connector is to be plugged, the terminal-side attachment surface and the socket-side attachment portion being integrally molded using a die from a synthetic resin.

According to a fourth aspect of the invention, the first positioning unit includes: a first positioning hole provided to one of the inverter cover and the terminal; and a first positioning projection provided to the other one of the inverter cover and the terminal, the first positioning projection being configured to be fitted into the first positioning hole, and the second positioning unit includes: a second positioning hole provided to one of the inverter cover and the terminal case; and a second positioning projection provided to the other one of the inverter cover and the terminal case, the second positioning projection being configured to be fitted into the second positioning hole.

In the first aspect of the invention, the first and second positioning units are provided to the members of the inverter, the first positioning unit allowing the terminal to be positioned relative to the inverter cover with a high accuracy, the second positioning unit allowing the terminal case to be positioned relative to the inverter cover with a high accuracy. As a result, the terminal and the terminal case are appropriately positioned relative to each other with reference to the inverter cover. The inverter cover, the terminal and the terminal case can thus be easily positioned relative to one another without using a typical positioning jig.

In the second aspect of the invention, since the inverter cover, the terminal and the terminal case are appropriately positioned relative to one another, the connector can be inserted through the connector-insertion opening of the terminal case with an appropriate gap between the seal surface of the terminal case and the outer circumferential surface of the connector, the gap being reliably sealable by the seal member. Further, as long as the positioning is appropriately performed, the connector can be plugged into (i.e., electrically connected to) the terminal in a good state without any stress on a connected part, which results in an improved durability.

In the third aspect of the invention, the terminal block, which is a synthetic resin molded product, includes the terminal-side attachment surface and socket-side attachment portion that are integrally molded using a die. Therefore, when a part of the first positioning unit is provided to the terminal-side attachment surface, the socket attached to the socket-side attachment portion and the part of the first positioning unit can be positioned relative to each other with an improved accuracy. This results in a good dimensional accuracy of the terminal and thus in smooth and reliable plugging of the plug of the connector into the socket.

In the forth aspect of the invention, the first positioning unit includes the first positioning hole and the first positioning projection, and the second positioning unit includes the second positioning hole and the second positioning projection. The positioning can thus be reliably performed by simple male-female fitting of these projections and holes, which contributes to a prompt and reliable assembly process of the inverter.

### BRIEF DESCRIPTION OF DRAWING(S)

FIG. 1 is an exploded perspective view showing an inverter according to an exemplary embodiment of the invention.

FIG. 2 is a perspective view showing a first positioning unit and a second positioning unit.

FIG. 3 is a perspective view showing a terminal.

FIG. 4 is a perspective view showing a relevant part of a terminal case. FIG. 5 is a sectional view showing a positioned state using the second positioning unit.

### DESCRIPTION OF EMBODIMENT(S)

An exemplary embodiment of the invention will be described below with reference to the attached drawings.

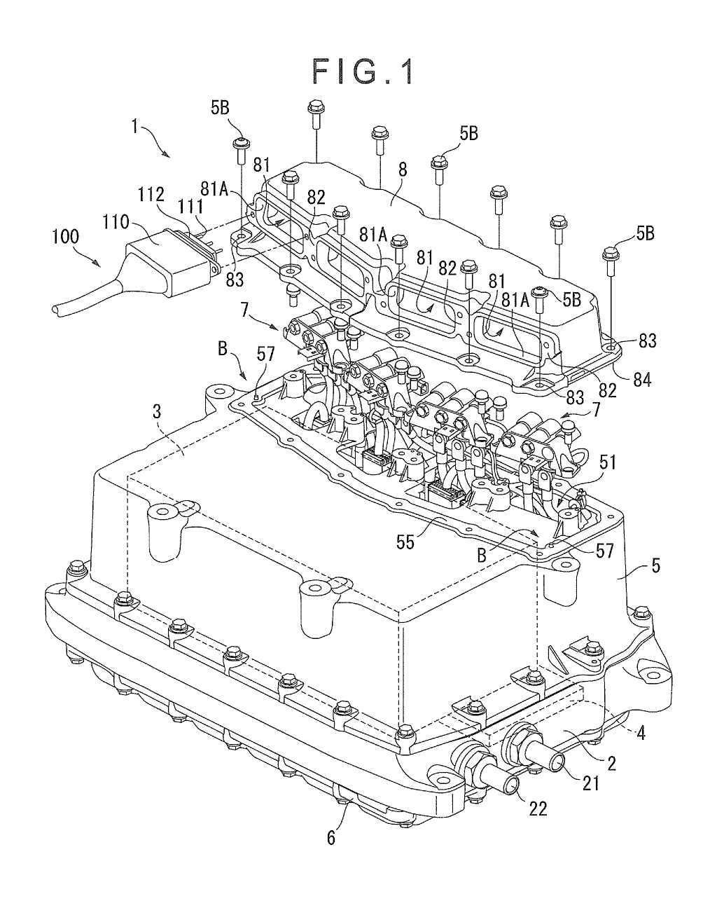

FIG. 1 is an exploded perspective view showing an inverter 1 according to the exemplary embodiment.

As shown in FIG. 1, the inverter 1 is a control unit for a hybrid hydraulic excavator that includes a crawler undercarriage, working equipment including a boom, an arm and a bucket, and a rotary upper structure provided on the crawler undercarriage, the crawler undercarriage and the working equipment being hydraulically driven, the rotary upper structure being driven with electric energy, as described in “BACKGROUND ART”. The inverter 1 controls an operation for storing in a capacitor an electric power generated by a power-generating motor driven by an engine or regenerated by a rotary electric motor during braking the rotary upper structure and an operation for supplying the electric power from the capacitor to the rotary electric motor.

Specifically, the inverter 1 includes: a water-cooling cooler 2; a step-up transformer 3 (an electronic component) disposed on an upper surface of the cooler 2; and a plurality of driving elements 4 disposed on a lower surface of the cooler 2 (only one of them is shown by dotted lines in FIG. 1), the driving elements 4 including an IGBT (Insulated Gate Bipolar Transistor) for driving the power-generating motor and an IGBT for driving the rotary electric motor in the hydraulic excavator.

The water-cooling cooler 2 has a side surface provided with a cooling water inlet 21 and a cooling water outlet 22 that are in communication with the cooling water circuit in the cooler 2. A cooling water flowing through the cooling water circuit cools the step-up transformer 3 attached on the upper surface of the cooler 2 and a heat sink for the driving elements 4 attached on the lower surface of the cooler 2. Further, the upper surface of the cooler 2 is attached with a metal upper cover 5 (an inverter cover) for covering the step-up transformer 3, and the lower surface of the cooler 2 is attached with a synthetic resin lower cover 6 for covering the driving elements 4.

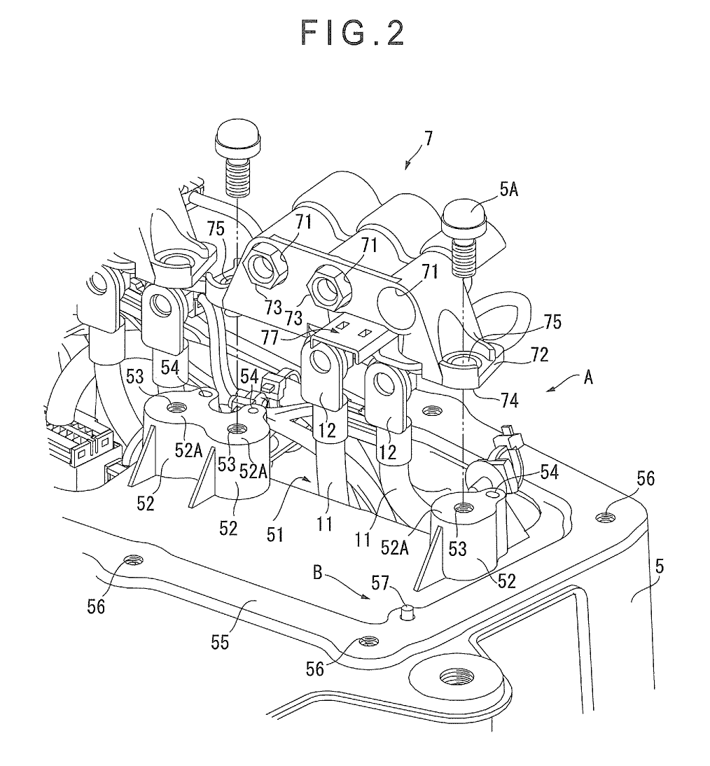

The upper cover 5 has an upper surface provided with an opening 51 for drawing out a plurality of cables 11 (labeled with the reference numeral in FIG. 2) of the step-up transformer 3 and the driving elements 4 in the upper cover 5, the opening 51 being defined along a side of the upper surface of the upper cover 5. The cables 11 are bonded to a plurality of terminals 7 arranged side by side so that the terminals 7 are electrically connected to the step-up transformer 3 and the driving elements 4. The terminals 7 are attached to the upper cover 5 and covered by a substantially rectangular terminal case 8 together with the opening 51. The terminal case 8 is also attached to the upper cover 5.

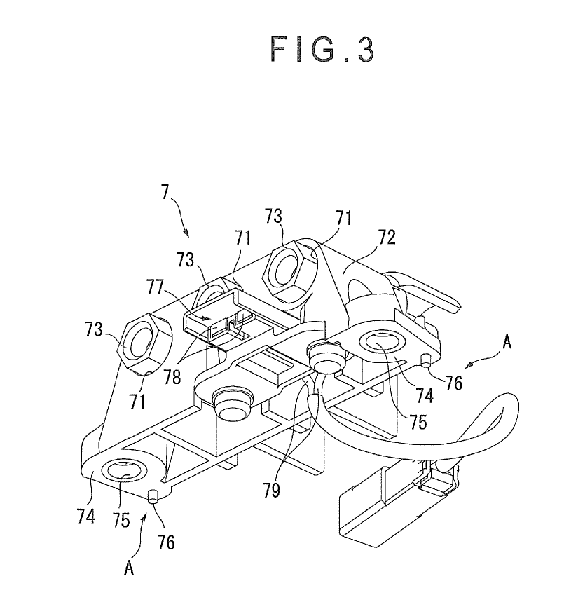

The terminal case 8 is provided with a plurality of connector-insertion openings 81 arranged side by side at positions corresponding to the terminals 7. The periphery of each of the connector-insertion openings 81 serves as a connector attachment portion 82 to which a connector 110 of a power cable 100 is, for instance, bolted. The connector 110, which includes a plug 111, is to be plugged into/unplugged from a later-described socket 73 of one of the terminals 7 (FIGS. 2 and 3). The electric power is thus transmitted through the power cable 100 between the inverter 1 and the power-generating motor or the rotary electric motor (not shown) and between the inverter 1 and the capacitor disposed below the inverter 1.

The connector 110 of the power cable 100 has an outer circumferential surface attached with an annular seal member 112. When the connector 110 is attached to the connector attachment portion 82, the seal member 112 comes into close contact with a seal surface 81A defined in an inner circumferential surface of the connector-insertion opening 81 to function as an inner-surface seal exhibiting a sufficient waterproof performance between the seal surface 81A and the outer circumferential surface of the connector. Further, when the connector 110 is attached to the connector attachment portion 82, the plug 111 of the connector 110 is plugged in the socket 73 of the one of the terminals 7 to be electrically connected thereto.

In other words, the connector 110 of the power cable 100 needs to be smoothly plugged into one of the terminals 7 while ensuring the waterproof performance relative to the terminal case 8. Accordingly, in the exemplary embodiment, a relative positional relationship between the terminals 7 and the terminal case 8 is strictly defined. With a deviation of the positional relationship between the terminals 7 and the terminal case 8, the seal member 112 is unlikely to be well in contact with the seal surface 81A irrespective of whether or not the plug 111 of the connector 110 is smoothly plugged into the socket 73 of one of the terminals 7, and thus cannot exhibit a sufficient sealing performance. However, even when the connector 110 is attached to the terminal case 8 in such a manner that the seal member 112 and the seal surface 81A are well in contact with each other, the plug 111 could be forcefully plugged into the socket 73 with a positional deviation. In this case, an electrically connected (plugged) part may be subjected to stress to be damaged.

In the exemplary embodiment, in order to bring the terminals 7 and the terminal case 8 into an accurate relative positional relationship, the terminals 7 are attached to the upper cover 5 via a first positioning unit A, whereas the terminal case 8 is attached to the upper cover 5 via a second positioning unit B. The terminals 7 and the terminal case 8 can thus be accurately attached at respective predetermined positions thereof with reference to the upper cover 5, and the relative positional relationship therebetween can be highly accurately ensured without using a jig dedicated to positioning the terminals 7 and the terminal case 8.

FIG. 2 is a perspective view showing the respective parts of the first and second positioning units A, B provided on the upper cover 5 as seen obliquely from thereabove. FIG. 3 is a perspective view showing a part of the first positioning unit A provided on the terminal(s) 7 as seen obliquely from therebelow.

As shown in FIG. 2, cover-side attachment columns 52 each in the shape of a pear in a plan view are disposed along the inner periphery of the opening 51 of the upper cover 5. Each of the terminals 7 is attached using a pair of the cover-side attachment columns 52 spaced from each other at a predetermined interval. Adjacent ones of the cover-side attachment columns 52 are integrated with each other. The cover-side attachment columns 52 each have an upper surface 52A provided with a threaded screw hole 53. In order to attach each of the terminals 7 to the upper cover 5, a screw 5A is inserted through each of the longitudinally opposite ends of the each of the terminals 7 and screwed into the screw hole 53.

The upper surface 52A of each of the cover-side attachment columns 52 is also provided with a positioning hole 54 (a first positioning hole) adjacent to the screw hole 53. A pair of the cover-side attachment columns 52 used for attaching each of the terminals 7 are thus each provided with the positioning hole 54. In other words, all the cover-side attachment columns 52 are each provided with the positioning hole 54.

As shown in FIG. 3, the terminals 7 each include: a terminal bracket 72 provided with three socket-side attachment portions 71 arranged side by side and penetrating therethrough; and the socket 73 attached in one of the socket-side attachment portions 71 of the terminal bracket 72 with a first end thereof slightly projecting from the one of the socket-side attachment portions 71. The terminal bracket 72, which is a molded product of an insulating synthetic resin, includes the socket-side attachment portions 71 and later-described terminal-side attachment surfaces 74 that are molded using a die integrally with the socket-side attachment portions 71.

The socket 73 is made of an electrically conductive metal. The socket 71 has a first end where the plug 111 of the connector 110 attached to the terminal case 8 is inserted. The socket 73 has a second end serving as a terminal (not shown) connectable to any one of solderless terminals 12 of the cables 11 of the step-up transformer 3 and the driving elements 4. With the above arrangement, the power-generating motor, the rotary electric motor and the capacitor can be brought into electrical connection with one of the step-up transformer 3 and the driving elements 4 of the inverter 1 through the power cable 100, the terminal(s) 7 and the like.

Incidentally, as shown in FIG. 2, two of the socket-side attachment portions 71 should be each attached with the socket 73 in the case of transmitting an electric power in the form of direct current (e.g., an electric power transmitted between the inverter 1 and the capacitor), because two of the cables 11 are required for such transmission and thus one of the socket-side attachment portion 71 does not need to be attached with the socket 73. In contrast, in the case of transmitting an electric power in the form of alternate current (e.g., an electric power transmitted between the inverter 1 and the power-generating motor or between the inverter 1 and the rotary electric motor), three of the cables 11 are required and thus each of the socket-side attachment portions 71 should be attached with the socket 73 as shown in FIG. 3. The power cable 100 attached with the connector includes two or three of such cables bundled into a harness.

The terminal bracket 72 of each of the terminals 7 has lower surfaces opposite in a longitudinal direction thereof (identical to an aligning direction of the socket-side attachment portions 71), the lower surfaces each defining the terminal-side attachment surface 74 to be brought into contact with the cover-side attachment column 52. Each of the terminal-side attachment surfaces 74 is provided with a through hole 75 through which the screw 5A is to be inserted. Each of the terminal-side attachment surfaces 74 is further provided with a positioning projection 76 (a first positioning projection) integrated therewith, the positioning projection 76 being disposed adjacent to the through hole 75 to vertically face the positioning hole 54 of the cover-side attachment column 52. The positioning projection 76 projects downward and is fitted into the positioning hole 54 when each of the terminals 7 is screwed onto the cover-side attachment column 52.

In the exemplary embodiment, the positioning hole 54 of the upper cover 5 and the positioning projection 76 of each of the terminals 7 thus function as the first positioning unit A according to the invention. When the positioning hole 54 and the positioning projection 76 of the first positioning unit A are fitted, each of the terminals 7 can be attached to the upper cover 5 with an excellent positional accuracy.

Referring back to FIGS. 1 and 2, an annular flat cover-side attachment surface 55 where the terminal case 8 is to be attached is defined around the opening 51 of the upper cover 5. The cover-side attachment surface 55 is provided with a plurality of bolt holes 56 spaced at appropriate intervals. A bolt 5B is screwed into each of the bolt holes 56 after inserted thought a through hole 83 provided to the terminal case 8, thereby attaching the terminal case 8 to the upper cover 5.

A positioning pin 57 (a second positioning projection) is planted in the cover-side attachment surface 55A to be adjacent to each of a predetermined pair of the bolt holes 56 longitudinally spaced from each other at a wide interval. The positioning pin 57 projects upward toward the terminal case 8 to be attached.

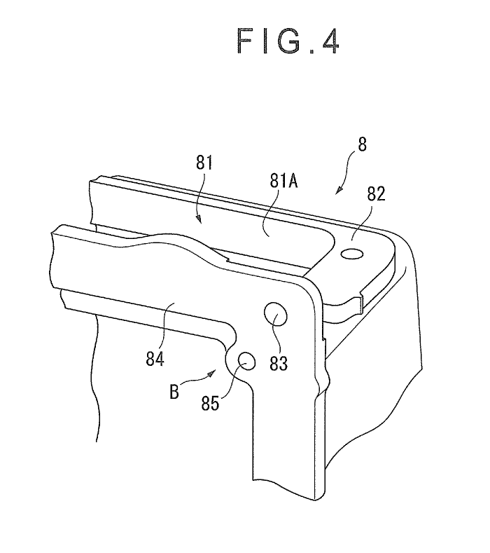

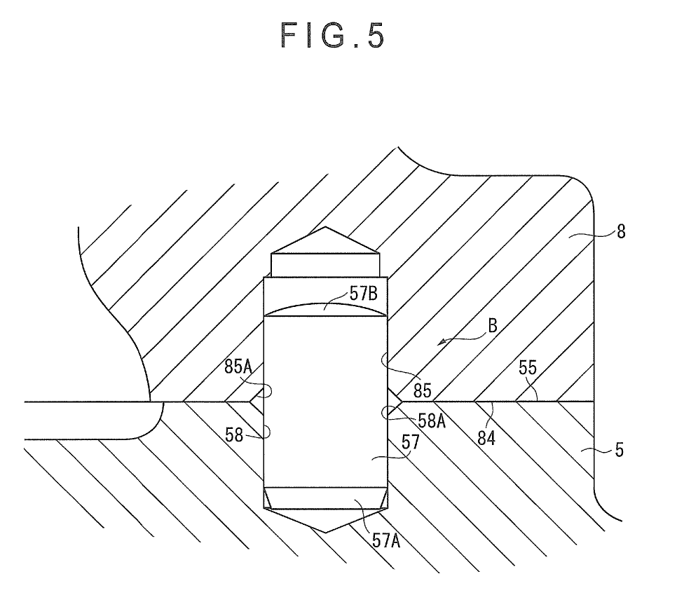

FIG. 4 is a perspective view showing a part of the terminal case 8 as seen obliquely from therebelow, the part of the terminal case 8 corresponding to the positioning pin 57 of the upper cover 5. The terminal case 8 has an annular case-side attachment surface 84 that is to be brought into contact with the cover-side attachment surface 55 of the upper cover 5. In addition to the through holes 83 corresponding to the bolt holes 56 of the upper cover, the case-side attachment surface 84 is further provided with a positioning hole 85 (a second positioning hole) adjacent to each of the through holes 83.

The positioning hole 85, which opens downward, is fitted onto the positioning pin 57 when the terminal case 8 is screwed onto the cover-side attachment column 55. FIG. 5 is a sectional view showing a fitting state of the positioning hole 85 and the positioning pin 57. As shown in FIG. 5, the positioning pin 57 is press-fitted in a press-in hole 58 provided to the cover-side attachment surface 55. The periphery of the opening of the press-in hole 58 is provided with a chamfer 58A. The positioning pin 57 has: a first end (a lower end in FIG. 5) that is to be press-fitted in the press-in hole 58 and is chamfered to have a tapered surface 57A; and a second end (an upper end in FIG. 5) that is to be fitted in the positioning hole 85 and has a spherical surface 57B. The periphery of the opening of the positioning hole 85 is likewise provided with a chamfer 85A.

In the exemplary embodiment, the positioning pin 57 of the upper cover 5 and the positioning hole 85 of the terminal case 8 function as the second positioning unit B according to the invention. When the positioning pin 57 and the positioning hole 85 of the second positioning unit B are fitted, the terminal case 8 can be attached to the upper cover 5 with an excellent positional accuracy.

When the terminals 7 and the terminal case 8 are attached to the upper cover 5 in the above manner, the terminals 7 and the terminal case 8 can be highly accurately positioned with reference to the upper cover 5 with the assistance of the first and second positioning units A, B, so that the terminals 7, the terminal case 8 and the upper cover 5 can be appropriately positioned to one another when attached. As a result, when the connector 110 of the power cable 100 is attached to the terminal case 8, the plug 111 of the connector 110 is reliably inserted into one of the terminals 7, which results in preventing, for instance, generation of unintended stress on the socket(s) 73 and the plug 111 and a poor sealing performance of the connector 110 relative to the terminal case 8.

Further, in the exemplary embodiment, as shown in FIGS. 2 and 3 on an enlarged scale, each of the terminals 7 is also provided with an interlock switch 77. The interlock switch 77 includes a pair of contact terminals 78, 78 spaced at a predetermined interval. Each of the contact terminals 78 is connected to a signal cable 79 (FIG. 3) connected to a detection circuit provided in the inverter 1. The interlock switch 77 is attached to detect whether or not the connector 110 of the power cable 100 (FIG. 1) is correctly inserted into one of the terminals 7.

Specifically, the connector 110 is provided with a contact conductor that is to bridge the contact terminals 78, 78 to establish electrical connection therebetween. When the connector 110 is attached to the terminal case 8 at a correct position and the plug 111 is reliably inserted into one of the terminal 7, the contact conductor comes into contact with the contact terminals 78, 78, so that the contact terminals 78, the signal cables 79 and the contact conductor are looped. A detection signal outputted from the detection circuit in the inverter 1 to one of the signal cable 79 is thus returned through the other signal cable 79 and detected by the detector circuit. When the signal is detected, it is determined that the connector 110 is attached to the terminal case 8 in a good condition.

Since the first and second positioning units A, B allow the contact conductor of the connector 110 to be in contact with the contact terminals 78 of the one of the terminals 7 at an appropriate position, the interlock switch 77 can properly work.

Incidentally, it should be understood that the scope of the invention is not limited to the above-described exemplary embodiment but includes modifications and improvements as long as the modifications and improvements are compatible with the invention.

For instance, although the inverter 1 includes the cooler 2, the upper cover 5 for covering the upside of the cooler 2, and the lower cover 6 for covering the underside of the cooler 2 in the exemplary embodiment, an inverter according to the invention may alternatively include a box-shaped case, an electronic component housed in the box-shaped case, and an inverter cover for covering the upside of the box-shaped case. In other words, as long as elements essential for the inverter according to the invention are provided, specific shapes and the like of these elements may be determined as desired in implementing the invention.

Although the inverter 1 is installed in a hybrid hydraulic excavator in the exemplary embodiment, an inverter according to the invention may alternatively be installed in any other hybrid construction machine such as a wheel loader and a dump truck. Further, in addition to a construction machine, an inverter according to the invention may be installed in an agricultural machine such as a hybrid tractor and a work vehicle such as a hybrid forklift. In other words, an inverter according to the invention is installable in any hybrid work machine including construction machine, agricultural machine and work vehicle. An inverter according to the invention may, of course, be installed not in a hydraulic work machine but in an electric work machine.

Although the terminal bracket 72 is a one-piece synthetic resin component in the exemplary embodiment, a bracket according to the invention may alternatively include two components including an insulating synthetic resin attachment member where the electrically conductive socket(s) 73 is to be attached and a metal plate fixed to the attachment member.

Although in the exemplary embodiment, the positioning hole(s) 54 is provided to the upper cover 5 as the first positioning hole of the first positioning unit A, whereas the positioning projection(s) 76 is provided to each of the terminals 7 as the first positioning projection of the first positioning unit A, the first positioning projection may alternatively be provided to the upper cover 5, whereas the first positioning hole is provided to each of the terminals 7. Similarly, although in the exemplary embodiment, the positioning hole(s) 85 is provided to the terminal case 8 as the second positioning hole of the second positioning unit B, whereas the positioning pin(s) 57 is provided to the upper cover 5 as the second positioning projection of the second positioning unit B, the second positioning hole may alternatively be provided to the upper cover 5, whereas the second positioning projection is provided to the terminal case 8.

### INDUSTRIAL APPLICABILITY

The invention is applicable not only to hybrid or electric construction machines but also to work machines including agricultural machines and work vehicles.

### EXPLANATION OF CODE(S)

1 . . . inverter, 3 . . . step-up transformer (electronic component), 5 . . . upper cover (inverter cover), 7 . . . terminal, 8 . . . terminal case, 54 . . . positioning hole (first positioning hole), 57 . . . positioning pin (second positioning projection), 71 . . . socket-side attachment portion, 72 . . . terminal bracket, 73 . . . socket, 74 . . . terminal-side attachment surface, 76 . . . positioning projection (first positioning projection), 81 . . . connector-insertion opening, 81A . . . seal surface, 85 . . . positioning hole (second positioning hole), 110 . . . connector, 111 . . . plug, 112 . . . seal member, A . . . first positioning unit, B . . . second positioning unit

1. An inverter comprising:
an electronic component;
an inverter cover for covering the electronic component;
a terminal attached to the inverter cover and electrically connected to the electronic component;
a terminal case attached to the inverter cover to cover the terminal, the terminal case being attachable with a connector to be plugged into and unplugged from the terminal;
a first positioning unit provided to the inverter cover and the terminal to position the inverter cover and the terminal relative to each other; and
a second positioning unit provided to the inverter cover and the terminal case to position the inverter cover and the terminal case relative to each other.

2. The inverter according to claim 1, wherein:
the terminal case is provided with a connector-insertion opening through which the connector is inserted, and
the connector-insertion opening has an inner circumferential surface defining a seal surface to be brought into close contact with a seal member provided to an outer circumferential surface of the connector.

3. The inverter according to claim 1, wherein the terminal comprises a terminal bracket comprising:
a terminal-side attachment surface to be brought into contact with the inverter cover; and
a socket-side attachment portion attached with a socket into which a plug of the connector is to be plugged, the terminal-side attachment surface and the socket-side attachment portion being integrally molded using a die from a synthetic resin.

4. The inverter according to claim 1, wherein:
the first positioning unit comprises:
a first positioning hole provided to one of the inverter cover and the terminal; and
a first positioning projection provided to the other one of the inverter cover and the terminal, the first positioning projection being configured to be fitted into the first positioning hole, and
the second positioning unit comprises:
a second positioning hole provided to one of the inverter cover and the terminal case; and
a second positioning projection provided to the other one of the inverter cover and the terminal case, the second positioning projection being configured to be fitted into the second positioning hole.
